(19) United States
(12) Patent Application Publication
(10) Pub. No.: US 2008/0037326 A1
(43) Pub. Date: Feb. 14, 2008

(54) XIP FLASH MEMORY DEVICE AND PROGRAM METHOD

(75) Inventors: Ho-Jung KIM, Suwon-si (KR); Seung-Kue JO, Yongin-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/781,379

(22) Filed: Jul. 23, 2007

(30) Foreign Application Priority Data
Aug. 10, 2006 (KR) 10-2006-0075714

(51) Int. Cl. G11C 16/04; G11C 16/06

(52) U.S. Cl. 365/185.18; 365/185.22; 365/185.25

(57) ABSTRACT

A memory cell in flash memory device is provided which includes a memory cell transistor having a control gate coupled to a word line and a drain coupled to a bit line; and a selection transistor for connecting a source of the memory cell transistor and a common source line in response to a selection signal.

### CROSS-REFERENCE TO RELATED APPLICATIONS

This U.S. non-provisional patent application claims priority under 35 U.S.C §119 to Korean Patent Application 10-2006-0075714 filed on Aug. 10, 2006, the subject matter of which is hereby incorporated by reference.

### BACKGROUND OF THE INVENTION

1. Field of the Invention

The present invention relates to semiconductor memory devices. More particularly, the invention relates to flash memory devices having memory cells capable of being programmed and erased at high speed.

2. Description of the Related Art

Many contemporary mobile systems incorporate an XIP (eXecution In Place) functionality when available memory is relatively small, and/or when a short boot time is demanded. In one aspect, XIP technology enables a flash memory incorporated within a mobile system to execute code stored in the flash memory without first transferring the code to RAM. In this manner, XIP technology allows the overall memory system to be smaller without necessarily limiting the execution performance of the memory system in relation to a plurality of application programs running on the mobile system.

Initially, only NOR-type flash memory systems incorporated the XIP functionality. More recently, however, NAND-type flash memory system (replacing NOR-type flash memory systems) have begun to incorporate XIP technology. (Hereafter, a NAND-type flash memory system incorporating one or more aspects of XIP functionality will be referred to as an “XIP flash memory”).

As is well understood in the art, the memory cell unit of a XIP flash memory includes a string selection transistor, a ground selection transistor, and a memory cell transistor. Figure (FIG.) 1 is a circuit diagram showing a conventional memory cell structure for a XIP flash memory. Referring to FIG. 1, the memory cell unit (MCU) of the XIP flash memory includes two selection transistors ST<x> and GT<x>, and one cell transistor MC<x>. While XIP flash memories typically include many thousands or millions of memory cells, the following explanation wilt be given for one memory cell unit (MCU) as exemplary of the many memory cell units forming the flash memory array.

The selection transistor ST<0> of the XIP flash memory is equivalent to the string selection transistor SST for a conventional NAND-type flash memory. The selection transistor GT<0> of the XIP flash memory is equivalent to the ground selection transistor GST of the conventional NAND-type flash memory. However, only a single memory cell transistor replaces the string of series-connected memory cell transistors typically associated with the conventional NAND-type flash memory. Thus, the memory cell unit MCU of the XIP flash memory is coupled to (and controlled in relation to) selection signal lines SSL<0> and GLS<0> and a word line voltage through a word line WL<0>, respectively.

The selection signal lines SSL<0> and GLS<0> and the word line WL<0> are conventionally coupled to a driver circuit (not shown in FIG. 1) which supplies the memory cell unit MCU with competent selection signals and word line voltages. In the illustrated example of FIG. 1, a memory cell unit 10 is coupled to a first bit line BL<0> through a first selection transistor ST<0>. Memory cell unit 10 is also coupled to a common source line CSL through a selection transistor GT<0>. A word line WL is coupled to the control gate of cell transistor MC<0>.

During programming of memory cell 10 in the XIP flash memory, a ground voltage of 0V (for data ‘0’) or supply voltage of VDD (for data ‘1’) is applied to the first bit line BL<0>. Supply voltage VDD is applied to the control gate of selection transistor ST<0>, and ground voltage is applied to the control gate of the selection transistor GT<0>. Then, a program voltage VPGM is applied to the word line WL. Under these applied voltage conditions, elections from the channel of the cell transistor MC<0> are injected into the floating gate of the cell transistor MC<0> via the conventionally understood Fowler-Nordheim tunneling (F-N tunneling) effect.

Because the foregoing programming operation (and similarly an erase operation) for the 3-transistor (TR) memory cell unit of the XIP flash memory is accomplished using F-N tunneling, the operation(s) may be performed at relatively high-speeds. Unfortunately, the XIP flash memory array implemented according to this memory cell unit design occupies a relatively large area, due to the plurality of selection lines required to program one memory cell unit.

### SUMMARY OF THE INVENTION

In one embodiment, the invention provides a memory cell unit in a flash memory, comprising; a memory cell transistor having a gate coupled to a word line and a drain coupled directly to a bit line without intervening selection transistor, and a selection transistor having a gate coupled to a selection signal line, the selection transistor connecting a source of the memory cell transistor to a common source line.

In another embodiment, the invention provides a flash memory device, comprising; a memory cell array including a plurality of memory cell units coupled to a plurality of bit lines, a switch circuit selecting between the plurality of bit lines and supplying a selected bit line with a set-up voltage, a write circuit supplying the selected bit line with a programming voltage corresponding to programming data, and a control circuit controlling the switch circuit to pre-charge the plurality of bit lines to the set-up voltage during a bit line set-up phase of a programming operation, and to cut off the set-up voltage to the selected bit line during a program execution phase of the programming operation.

In another embodiment, the invention provides a method of programming a flash memory device, the flash memory device comprising a plurality of memory cell units, each memory cell unit comprising a memory cell transistor having a gate coupled to a word line and a drain coupled directly to a bit line without intervening selection transistor, and a selection transistor having a gate coupled to a selection signal line, the selection transistor connecting a source of the memory cell transistor to a common source line; the method comprising; charging bit lines coupled to the plurality of memory cell units to a set-up voltage, but inhibiting development of the set-up voltage on a bit line associated with a selected memory cell unit, and thereafter biasing the bit line associated with the selected memory cell unit to either ground or a floating state in accordance with programming data.

### BRIEF DESCRIPTION OF THE DRAWINGS

Embodiments of the invention will be described with reference to the accompanying drawings, wherein like reference numerals refer to like or similar elements. In the drawings:

FIG. 1 is a circuit diagram of a cell structure for a conventional XIP flash memory;

FIG. 2 is a circuit diagram illustrating a cell structure for an XIP flash memory according to an embodiment of the invention;

FIG. 3 is a block diagram further illustrating a functional structure for an XIP flash memory device according to an embodiment of the invention;

FIG. 4 is a circuit diagram further illustrating the switch circuit of FIG. 3;

FIG. 5 is a timing diagram further illustrating a programming operation for an XIP flash memory according to an embodiment of the invention; and

FIG. 6 is a table listing exemplary bias conditions for respective operations associated with an XIP flash memory device according to an embodiment of the invention.

### DESCRIPTION OF EMBODIMENTS

The present invention will now be described in the context of several embodiments with reference to the accompanying drawings. The invention may, however, be embodied in many different forms and should not be construed as being limited to only the illustrated embodiments. Rather, these embodiments are presented as teaching examples.

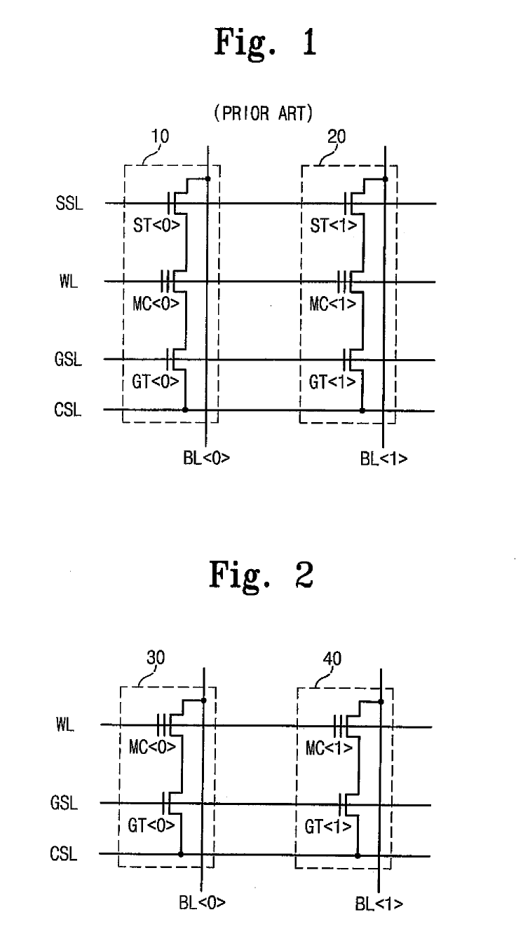

FIG. 2 is a circuit diagram of an XIP flash memory according to an embodiment of the invention. Referring to FIG. 2, the memory cell structure of the XIP flash memory differs from the conventional memory cell structure illustrated in FIG. 1 by the omission of a selectibn transistor ST<x>. With the removal of selection transistor ST<x>, selection signal line SSL is no longer needed in the XIP flash memory according to an embodiment of the invention. As a result, the size of the memory cell array may be reduced. Moreover, the driver circuit controlling operation of the memory cell array may be simplified in its implementation and operation.

With reference to FIG. 2, memory cell unit 30 is coupled between a common source line CSL and a first bit line BL<0>. Connection to the common source line CSL is made through a selection transistor GT<0>. Thus, only two active elements, memory transistor MC<0> and selection transistor GT<0>, form memory cell unit 30, and memory cell unit 30 is selected through a single selection line GSL. The gate of the memory transistor MC<0> is coupled to the word line WL. In the illustrated example, the drain of the memory transistor MC<0> is coupled to the first bit line BL<0>. The source of the of the memory transistor MC<0> is coupled to the common source line CSL through selection transistor GT<0> having its gate coupled to the selection line GSL.

It is understood in this descriptive context that memory cell unit 30 is indicative of an array of memory cell units forming an XIP flash memory according to an embodiment of the invention.

With this configuration, memory cell unit 30 may conventionally execute all necessary operations, except the programming operation, using bias conditions typically associated with the conventional XIP flash memory. An exemplary control system and method of programming the XIP flash memory according to an embodiment of the invention will be described in some additional detail hereafter.

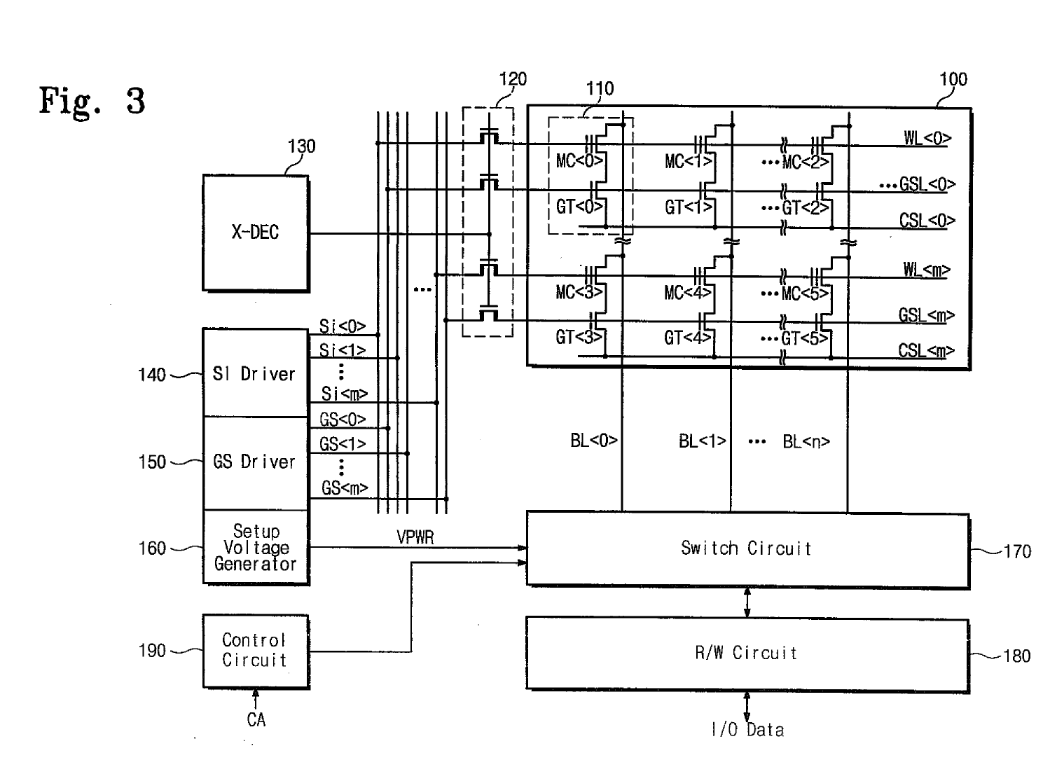

FIG. 3 shows a block diagram of a flash memory device incorporating a memory cell structure consistent with an embodiment of the invention. Referring to FIG. 3, a memory cell array 100 comprises a plurality of memory cell units 110, each implemented with a single selection transistor GT<n>. Accordingly, the structure of the memory cell unit requires bit line control circuits that support programming and erase operations accomplished via the F-N tunneling effect.

Each memory cell unit 110 in memory cell array 100 is coupled to a corresponding bit line. That is, each memory cell unit is located at a respective intersection between a word line WL and a bit line BL. Thus, each bit line BL<n> connects a plurality of memory cell units 110 along its length, but no conventionally provided selection transistors ST<x> are present to connect each memory cell unit 110 to its corresponding bit line.

A high voltage switch circuit 120 supplies word line voltages to the control gate of each memory transistor MC<n>, and selection voltages to the control gate of each selection transistor GT<n>. High voltage switch circuit 120 is responsive to an X-Decoder 130. Thus, high voltage switch circuit 120 is controlled to select one or more individual memory cell units 110 in accordance with an address signal received by X-Decoder 130.

For example, X-Decoder 130 may select a specific portion of memory cell array 110 (e.g., a page of memory cell units) in response to a received row address. That is, X-Decoder 130 will turn ON particular switches in high voltage switch circuit 120 in order to transmit a desired word line voltage and selection voltage across memory cell array 100.

A word line driver 140 may be used to supply word line voltages to the word lines WL<m> in memory cell array 100. During a programming operation in one embodiment of the invention, word line driver 140 may supply a word voltage having a stepped pulse waveform.

Similarly, a ground selection voltage driver 150 may be used to supply selection voltages to the selection lines GSL<m> in memory array 100.

A set-up voltage generator 160 may be used to generate a set-up voltage VPWR supplied to the bit lines BL<n> of memory cell array 100. In particular, during bit line setup and programming operation execution, the setup voltage generator 160 supplies the set-up voltage VPWR to the bit lines. The set-up voltage VPWR generated by set-up voltage generator 160 develops a channel voltage in unselected memory cell units that inhibits programming. That is, although a program voltage VPGM is applied to a word line of an unselected memory cell unit MC<x>, an electric field sufficient to cause F-N tunneling does not develop in relation to the channel. For example, the level of the set-up voltage VPWR may be equivalent to the voltage level of a pass voltage VPASS (e.g., 7 to 8V) for a conventional NAND flash memory.

A switch circuit 170 supplies the set-up voltage VPWR generated by set-up voltage generator 160 to the bit lines during programming operations. Switch circuit 170 also selects between bit lines in response to a control signal received from a control circuit 190 and therbby facilitates the programming of data received from a read/write circuit 180. In this manner, switch circuit 170 may set selected bit lines to a floating state or a discharged state.

Read/write circuit 180 applies a voltage (VDD or 0V) corresponding to the data to be programmed via the bit lines selected by switch circuit 170 during a programming operation. During a read operation, read/write circuit 180 reads the programmed data by sensing respective bit lines of the memory cells and outputs the read data.

Control circuit 190 controls switch circuit 170 in response to a received column address (CA). Control circuit 190 controls switch circuit 170 so as to execute a bit line setup operation, a programming execution operation and a recovery operation during the programming operation. Switch circuit 170 supplies the bit lines with a voltage corresponding to the I/O data from read/write circuit 180.

As noted above, XIP flash memory according to an embodiment of the invention comprises one selection transistor per memory cell unit. Although the XIP flash memory only has one selection transistor per memory cell unit, it is still possible to perform a fast programming operation using F-N tunneling under control of switch circuit 170 and control circuit 190.

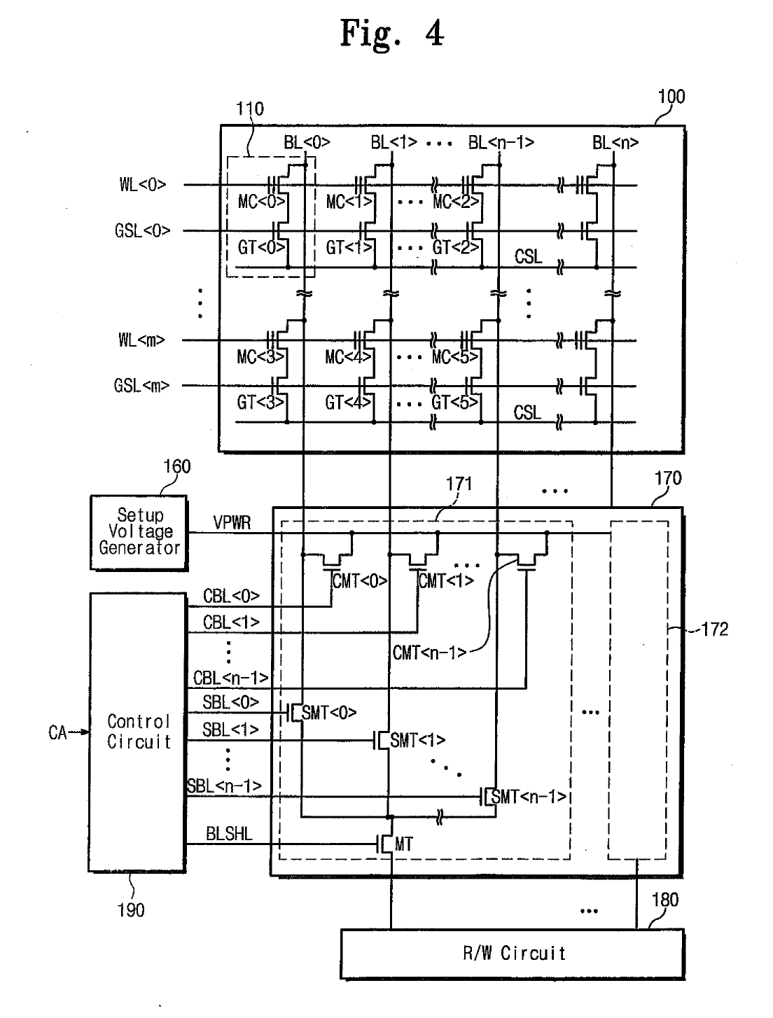

FIG. 4 is a circuit diagram further illustrating bit line control operations for the XIP flash memory of FIG. 3 during a programming operation. Referring to FIG. 4, switch circuit 170 selects a bit line and applies a bit line voltage to the selected bit line under the control of control circuit 190. Through the selection operation of switch circuit 170, both programming and erase operations may be executed using the F-N tunneling effect.

Switch circuit 170 is coupled to bit lines BL<n> of memory cell array 100. Switch circuit 170 may comprise a plurality of switch units 171˜172. Each switch unit 171˜172 controls a designated portion of the plurality of bit lines BL<n> in memory cell array 100. Under the control of control circuit 190, the set-up voltage VPWR from set-up voltage generator 160 is applied to selected bit lines Then, a bit line data voltage is applied to the bit lines in accordance with program data from read/write circuit 180.

A more detailed operation of the switch circuit 170 will be set forth as follows. The set-up voltage VPWR from set-up voltage generator 160 is transmitted through a charge switch CMT<n> under control of control circuit 190. During the bit line set up operation, the set-up voltage VPWR is applied to each of the bit lines. The set-up voltage VPWR is transmitted or cut-off to each of the bit lines by a corresponding charge switch CMT<n>. Each charge switch CMT<n> is controlled by a corresponding switch control signal CBL<n>. Furthermore, each of the bit lines is coupled to read/write circuit 180 via selection switches SMT<n> and a main switch MT under the control of control circuit 180.

During a programming operation, the bit line data voltage from read/write circuit 180 is provided to a selected bit line through a corresponding selection switch SMT<n> and main switch MT. It will be evident to those skilled in the art that the charge switches CMT<n> and selection switches SMT<n> should be formed from relatively high-voltage switches.

Through the bit line bias operation of switch circuit 170, a fast programming operation accomplished via F-N tunneling effects may be executed. Switch circuit 170 pre-charges the bit lines BL<n> with the set-up voltage VPWR. During a program execution phase, switch circuit 170 discharges the bit line of a selected memory cell unit, and the programming voltage is applied to the word line associated with the selected memory cell unit. As a result, a fast programming operation accomplished via F-N tunneling is executed in the memory cell unit having one selection transistor.

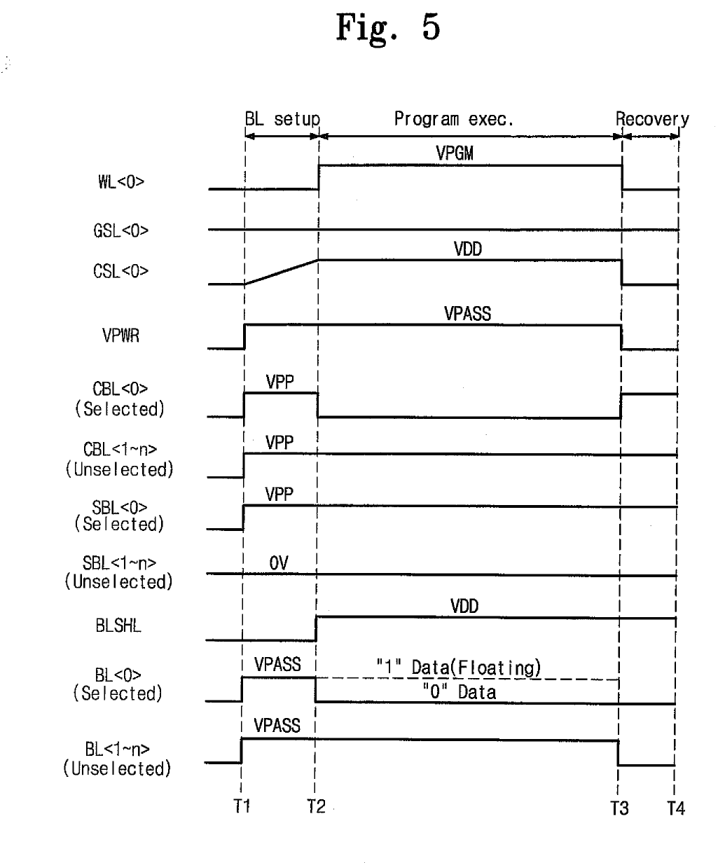

FIG. 5 is a timing diagram illustrating various control signal waveforms applied to individual memory cell units 110 depicted in FIG. 4. In order to program a memory cell unit 110, a programming operation comprises a bit line setup phase, a programming execution phase, and a recovery phase.

At the beginning of the bit line setup phase of programming memory cell unit 110, control circuit 190 outputs the switch control signals CBL<n> corresponding to respective bit lines. Control circuit 190 charges all bit lines to the setup voltage VPASS through switch control signals CBL<n>. During the bit line setup phase, the voltage of the common source line CSL rises to supply voltage VDD. At this time, switch circuit 170 supplies the setup voltage from setup voltage generator 160 to the respective bit lines. Control circuit 190 outputs switch control signals CBL<n> in order to turn ON each of the charge switches CMT<n>. Then, control circuit 190 outputs a control signal BLSHL to turn ON the selection switch SMT<0> corresponding to a selected bit line, and to cut off the main switch MT. Under these bias conditions, all bit lines are pre-charged to the setup voltage VPASS.

When the bit line setup operation is completed, programming execution phase follows. During the programming execution phase, a ground voltage (0V) is supplied to the bit line BL<n> of the selected memory cell unit so as to fix the channel voltage of the cell transistor to ground voltage (0V). At the same time, control circuit 190 turns OFF the corresponding charge switch CMP<n> coupled to the selected bit line BL<n>. Switch circuit 170 transmits the bit line data voltage that corresponds to the program data from read/write circuit 180.

In a case where the program data is “1” the channel voltage of the cell transistor should be held at the setup voltage VPASS level, or should be boosted to the setup voltage. During the program execution phase, the corresponding charge switch CMT<n> is turned OFF while the selection switch SMT<n> is turned ON.

The control signal BLSHL is applied to the main switch MT connecting read/write circuit 180 and bit lines BL<n>. The voltage level of the control signal BLSHL is that of internal supply voltage VDD. Read/write circuit 180 applies the source voltage VDD according to the program data ‘1’ to the source of the main switch MT. Under these conditions, the main switch MT is substantially cut off because the gate voltage (being VDD) and a source voltage of the main switch MT are equivalent to each other (i.e. Vgs<Vth).

The selected bit line BL<n> and the channel of the selected cell transistor MC<n> are set to a floating state because the selection transistor GT<0> is turned OFF by the selection signal GSL<0>. Even though the program voltage VPGM is applied to the word line WL<0> under the condition, unselected memory cells MC<n> are inhibited from being programmed by a boosting effect. Consequently, the selected memory cell MC<n> is set to a state of a threshold voltage corresponding to data ‘1’.

In a case where the program data is ‘0’, the pre-charged setup voltage VPASS on the selected bit line BL<n> should be discharged to a ground voltage (0V). During the program execution phase, the corresponding charge switch CMT<n> is turned OFF and the selection switch SMT<0> is turned ON. At the same time, the control signal BLSHL (VDD) is applied to the main switch MT so as to connect read/write circuit 180 with the bit lines BL<n>. Read/write circuit 180 applies ground voltage (0V) corresponding to program data 0' to the source of the main switch MT. The main switch MT is turned ON by the control signal BLSHL so that the pre-charged setup voltage on the bit line BL<0> is discharged. At the same period, the program voltage VPGM is applied to the gate of the selected memory cell MC<n> to develop an electric field sufficient to cause F-N tunneling between the channel and gate of the selected memory cell MC<n>. Consequently, the program data ‘0’ is programmed into the selected memory cell MC<n>.

The pre-charged setup voltage VPASS on the unselected bit lines BL <n> is maintained during the programming execution phase. In the illustrated example, the waveform of the program voltage VPGM is shown as a rectangular pulse, but it might be a voltage consistent with well understood Incremental Step Pulse Programming (ISSP) techniques.

The recovery phase follows the program execution phase. During the recovery phase, all bit lines are returned to a ground voltage applied by setup voltage generator 160.

As described above, a memory cell unit according to an embodiment of the invention is biased through the bit line voltage by switch circuit 180 during a programming operation. As the bit line of the selected memory cell unit is capable of being discharged to ground, it is possible to perform the fast programming operation using F-N tunneling.

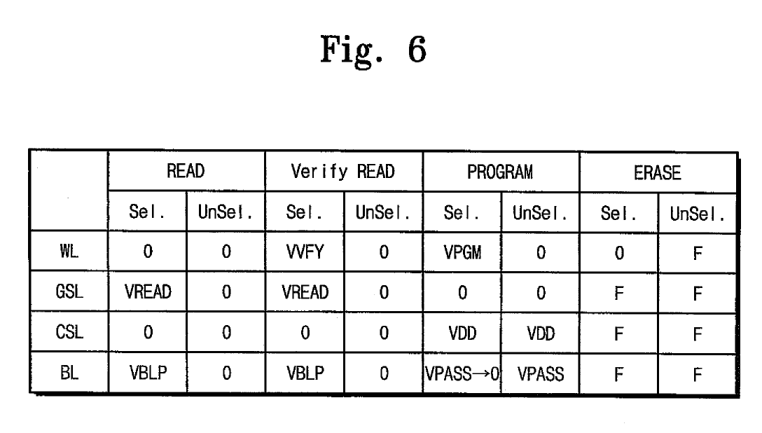

FIG. 6 is a table of exemplary bias conditions for various operations executed by the XIP flash memory according to an embodiment of the invention. Referring to FIG. 6, the bias conditions are generally similar to the conventional XIP flash memory, except for the programming operation. As described above in relation to FIGS. 4 and 5, the bit line voltage of the memory cell unit is set to a ground voltage level under the control of switch circuit 170.

During the read operation, the cell transistor MC of a selected memory cell unit is coupled to the common source line CSL by supplying the turn-on voltage VREAD to the selection line GSL. At this point, the bit line is supplied with the sensing voltage VBLP from read/write circuit 180. The bit lines of the unselected memory cell units are supplied with a ground voltage (0V).

The bias condition for the selected memory cell unit during a verify operation is the same as that of the selected memory cell unit during a read operation, except for the applied word line voltage. During the verify operation, a prescribed verify voltage VVFY is applied to the word line of the selected memory cell unit. In this way, a threshold Voltage state is sensed and amplified so as to detect PASS or FAIL.

During the erase operation, ground voltage is applied to the word line of the selected memory cell unit, and a high voltage (e.g., about 20V) is applied to the bulk area of the selected memory cell unit. Coincidently, the selection line, the bit line of the selected memory cell unit, and unselected word lines are biased with a floating state. Under the above described bias conditions, F-N tunneling will occur which causes electrons to migrate from/to the floating gate of a selected memory cell unit.

According to the above bias conditions and operative explanations, the memory cell unit of an XIP flash memory need not have the selection line SSL (i.e., a selection transistor connecting a bit line and memory cell transistor). On the whole, it is possible to reduce in the number of transistors per memory cell unit and simplify of the control operation. Thus, it is possible to secure a fast programming operation using F-N tunneling in the memory device having a reduced chip size.

Although the present invention has been described in connection with several embodiments illustrated in the accompanying drawings, it is not limited thereto. It will be apparent to those skilled in the art that various substitution, modifications and changes may be thereto without departing from the scope of the invention as defined by the following claims.

What is claimed is:

1. A memory cell unit in a flash memory, comprising:
a memory cell transistor having a gate coupled to a word line and a drain coupled directly to a bit line without intervening selection transistor; and
a selection transistor having a gate coupled to a selection signal line, the selection transistor connecting a source of the memory cell transistor to a common source line.

2. The memory cell of claim 1, wherein during a program operation, the selection transistor is turned OFF and a programming voltage corresponding to programming data is applied to the bit line.

3. The memory cell of claim 2, wherein the bit line is pre-charged to a prescribed voltage during a bit line setup phase of the program operation.

4. The memory cell of claim 3, wherein the bit line is discharged to ground voltage; the selection transistor decouples the source of the memory cell transistor from the common source line; and the programming voltage corresponding to the programming data is supplied to the word line during a program execution phase of the program operation.

5. The memory cell of claim 1, wherein the memory cell transistor is programmed and erased by F-N tunneling.

6. A flash memory device, comprising:
a memory cell array including a plurality of memory cell units coupled to a plurality of bit lines;
a switch circuit selecting between the plurality of bit lines and supplying a selected bit line with a set-up voltage;
a write circuit supplying the selected bit line with a programming voltage corresponding to programming data; and
a control circuit controlling the switch circuit to pre-charge the plurality of bit lines to the set-up voltage during a bit line set-up phase of a programming operation, and to cut off the set-up voltage to the selected bit line during a program execution phase of the programming operation.

7. The flash memory device of claim 6, wherein each of the plurality of memory cell units comprises:
a memory cell transistor having a gate coupled to a word line and a drain coupled directly to a bit line without intervening selection transistor; and
a selection transistor having a gate coupled to a selection signal line, the selection transistor connecting a source of the memory cell transistor to a common source line.

8. The flash memory device of claim 6, wherein the switch circuit comprises:
a plurality of charging switches respectively supplying the set-up voltage to the plurality of bit lines;
a main switch receiving the programming voltage from the write circuit; and
a plurality of selection switches respectively connecting the plurality of bit lines to the main switch.

9. The flash memory of claim 8, wherein each of the plurality of charging switches is turned ON during the bit line set-up phase of the programming operation.

10. The flash memory of claim 8, wherein during the program operation, the control circuit turns OFF a charging switch corresponding to the selected bit line and turns ON the selection transistor corresponding to the selected bit line.

11. The flash memory of claim 8, wherein the main switch is turned OFF during a programming operation when the programming data is “1”.

12. The flash memory device of claim 11, wherein the bit line voltage is applied to a control gate of the main switch by the control circuit.

13. The flash memory device of claim 12, wherein the selected bit line is set to a floating state when the program data is “1” during a programming operation.

14. The flash memory device of claim 6, further comprising:
a word line voltage generator respectively supplying word line voltages to word lines associated with the plurality of memory cell units.

15. The flash memory device of claim 14, further comprising:
a selection signal generator generating the selection signal.

16. The flash memory device of claim 15, further comprising:
a set-up voltage generator generating the set-up voltage.

17. A method of programming a flash memory device, the flash memory device comprising a plurality of memory cell units, each memory cell unit comprising a memory cell transistor having a gate coupled to a word line and a drain coupled directly to a bit line without intervening selection transistor, and a selection transistor having a gate coupled to a selection signal line, the selection transistor connecting a source of the memory cell transistor to a common source line;
the method comprising:
charging bit lines coupled to the plurality of memory cell units to a set-up voltage, but inhibiting development of the set-up voltage on a bit line associated with a selected memory cell unit; and thereafter,
biasing the bit line associated with the selected memory cell unit to either ground or a floating state in accordance with programming data.

18. The program method of claim 17, wherein the charging bit lines comprises boosting a voltage on a common source line to a source voltage.

19. The program method of claim 17, wherein the biasing of the bit line comprises applying a programming voltage corresponding to the programming data to the word line of the selected memory cell transistor when a blocking voltage is applied to the selection transistor coupled to the selected memory cell transistor.

20. The program method of claim 19, wherein the bit line is set to a floating state when a program data is “1”, or the bit line is biased to ground when a program data is “0”.

21. The program method of claim 20, wherein the memory cell transistor of each memory cell unit in the plurality of memory cell units is programmed by F-N tunneling.
